(19) United States
(12) Patent Application Publication
(10) Pub. No.: US 2015/0115042 A1
(43) Pub. Date: Apr. 30, 2015

(54) CONTACTLESS INFORMATION MEDIUM, BOBBIN MEMBER FOR CONTACTLESS INFORMATION MEDIUM, BODY MEMBER FOR CONTACTLESS INFORMATION MEDIUM, AND METHOD FOR PRODUCING CONTACTLESS INFORMATION MEDIUM

(71) Applicant: NHK Spring Co., Ltd., Yokohama-shi (JP)

(72) Inventors: Masayuki Miura, Kanagawa (JP); Motoyuki Otsuka, Kanagawa (JP); Shuhei Okubo, Kanagawa (JP)

(73) Assignee: NHK SPRING CO., LTD., Yokohama-shi (JP)

(21) Appl. No.: 14/365,728

(22) PCT Filed: Dec. 5, 2012
(86) PCT No.: PCT/JP2012/081567

§ 371 Date: Jun. 16, 2014

(30) Foreign Application Priority Data
Dec. 28, 2011 (JP) 2011-288413

(51) Int. Cl. G06K 19/077; H01L 21/56

(52) U.S. Cl. CPC G06K 19/07781; G06K 19/07724; H01L 21/56
USPC 235/492; 438/26

(57) ABSTRACT

A contactless information medium includes: a body forming an outer shape of the contactless information medium; an IC chip housed in the body; a coil antenna which is formed of a string of conductive wire, both ends of the conductive wire being connected to the IC chip, and which includes a main arrangement pattern provided along a closed curve and a plurality of sub-arrangement patterns, each of which has a smaller diameter than the main arrangement pattern; and a plurality of bobbins provided in the body and arranged along the closed curve, the string of conductive wire being wound around the plurality of bobbins along the closed curve to form the main arrangement pattern, the string of conductive wire being wound around each of the bobbins to form the sub-arrangement patterns.

### FIELD

The present invention relates to a contactless information, medium including an. IC chip and a coil antenna, a bobbin member for the contactless information medium, a body member for the contactless information medium, and a method for producing the contactless information medium. In the contactless information medium, the coil antenna is wound around the bobbin member for the contactless information medium. The body member for the contactless information medium forms a part of a body of the contactless information, medium.

### BACKGROUND

Recently, a contactless information medium including an IC chip and an antenna has been widely used in various fields, such as distribution, traffic, finance, entertainment, and amusement. For example, a coin-shaped contactless information medium is used as a token in a transportation facility, or used instead of a coin in an amusement facility (for example, see Patent Literatures 1 to 3). When a contactless information medium is used instead of a token or a coin, a value check and an authenticity determination thereof can be instantly performed by contactless communication with the contactless information medium.

The coin-shaped contactless information medium can be produced, for example, by arranging an IC chip and a coil, antenna into a plate-shaped body member which forms a part of the coin shape, and by covering these built-in components by injection molding. Also, when the weight like a real coin is required for the coin-shaped contactless information medium, a body of the coin-shaped contactless information medium may be formed from a material having high specific gravity, for example, as disclosed in Patent Literatures 1 to 3. Among these documents, in Patent Literature 3, a body of an IC card is formed from a material which includes metal having predetermined specific gravity and specific resistance in order to weight the IC card and to prevent the body of the card from interfering with communication between a built-in IC module and an external device.

On the other hand, Patent Literature 4 discloses a technique related to a coil antenna which performs communication between an IC chip and an external communication device. This coil antenna includes a winding pattern, which is spread into a part or a whole part of a main arrangement pattern forming a loop and which has a winding shape adequately smaller than that of the main arrangement pattern.

### CITATION LIST

### Patent Literature

Patent Literature 1: Japanese Patent Application Laid-open No. 2002-7989

Patent Literature 2: Japanese Patent Application Laid-open No. 2002-312745

Patent Literature 3: Japanese Patent Application Laid-open No. 2002-7991

Patent Literature 4: Japanese Patent Application Laid-open No. 2009-147560

### SUMMARY

### Technical Problem

Incidentally, in an amusement facility, a plurality of (for example, ten or more) coins used for a game and the like may be piled up when used. Thus, when a contactless information medium is used instead of the coin, there is a request to use the contactless information medium in a similar manner. However, when the plurality of contactless information media is piled us, electromagnetic mutual interference occurs. Thus, communication between each of the contactless information media and an external communication device is difficult when the plurality of contactless information media is piled up.

To solve such a problem, it is considered to apply a coil antenna, which includes a small winding pattern and is disclosed in Patent Literature 4, to a conventional contactless information medium. However, production steps become difficult and cumbersome when the coil antenna is applied to a coin-shaped contactless information medium.

First, it is difficult to form a winding pattern with an air core in a step of manufacturing the coil antenna. To form the winding pattern with an air core, special equipment is necessary and a general coil, winding machine cannot be used. Therefore, the production steps become cumbersome and manufacturing costs increase.

In addition, there is a step of attaching an air core coil to one surface of a two-sided adhesive film and attaching the other surface to a body member. In this step, it is not allowed to touch the adhesive surfaces and to make a mistake in attaching. Thus, the step requires an operation by a human hand.

Moreover, in a step of sealing an IC chip and the coil, antenna and forming the coin-shaped outer shape, the film may be melted by heat and pressure during injection molding and the pattern of the coil antenna may be destroyed. In this case, it becomes difficult to secure performance of the contactless information medium to communicate even when the plurality of contactless information media is piled up. It is time-consuming to obtain the stable performance, because it is necessary, for example, to attach a heat-resistant film to protect the pattern of the coil antenna.

In the view of the foregoing, the present invention has been made to provide a contactless information medium, a bobbin member for the contactless information medium, a body member for the contactless information medium, and a method for producing the contactless information medium. The contactless information medium can be easily produced, and when the plurality of contactless information media is piled up, each of the contactless information media can communicate with a communication device. In such a contactless information medium, a coil antenna is wound around the bobbin member for the contactless information medium. The body member for the contactless information medium forms a part of a body of the contactless information medium.

### Solution to Problem

To solve the problem described above and achieve the object, a contactless information medium according to the present invention includes: a body forming an outer shape of the contactless information medium; an IC chip housed in the body; a coil antenna which is formed of a string of conductive wire, both ends of the conductive wire being connected to the IC chip, and which includes a main arrangement pattern provided along a closed curve and a plurality of sub-arrangement patterns, each of which has a smaller diameter than the main arrangement pattern; and a plurality of bobbins provided in the body and arranged along the closed curve, the string of conductive wire being wound around the plurality of bobbins along the closed curve to form the main arrangement pattern, the string of conductive wire being wound around each of the bobbins to form the sub-arrangement patterns.

The above-described contactless information medium further includes an auxiliary bobbin which is arranged along the closed curve and makes the string of conductive wire, which forms the main arrangement pattern, jut out to a side of an outer periphery.

In the above-described contactless information medium, the body includes: a first member which forms a part of the body; and a second member which forms a part of the body and seals, with the first member, the plurality of bobbins, the IC chip, and the coil antenna, and the plurality of bobbins is connected to each of by a fixation member, which fixes the plurality of bobbins, and housed between the first member and the second member.

The above-described contactless information medium further includes a metal member arranged on a side of an outer periphery of the fixation member, the fixation member is arranged on a surface, located on an inner side of the contactless information medium, of the first member, with the plurality of bobbins facing a side of the second member, and the metal member is sealed inside the first member.

The above-described contactless information medium further includes a metal member arranged on a side of an outer periphery of the fixation member and sealed inside the second member.

In the above-described contactless information medium, the body includes: a first member which forms a part of the body; and a second member which forms a part of the body and seals, with the first member, the plurality of bobbins, the IC chip, and the coil antenna, and the plurality of bobbins is provided on a surface, located on an inner side of the contactless information medium, of either the first member or the second member.

The above-described contactless information medium further includes a metal member arranged on a side of an outer periphery of the plurality of bobbins, wherein the plurality of bobbins is provided on a surface, located on an inner side of the contactless information medium, of the first member, and the metal member is sealed inside the first member.

The above-described contactless information medium further includes a metal member arranged on a side of an outer periphery of the plurality of bobbins, the plurality of bobbins is provided on a surface, located on an inner side of the contactless information medium, of the first member, and the metal member is sealed by the first member and the second member.

The above-described contactless information medium further includes a metal member arranged on a side of an outer periphery of the plurality of bobbins, the plurality of bobbins is provided on a surface, located on an inner side of the contactless information medium, of the first member, and the metal member is sealed by the second member and a third member which is different from the first member.

In the above-described contactless information medium, the body is coin-shaped.

A bobbin member for a contactless information medium according to the present invention, around which bobbin member a conductive wire is wound to form a predetermined pattern of a coil antenna in the contactless information medium, includes: a plurality of bobbins arranged along a closed curve; and a fixation member which connects the plurality of bobbins to each other.

A body member for a contactless information medium according to the present invention, which body member forms a part of a body of the contactless information medium, includes: a plurality of bobbins arranged along a closed curve on a surface on an inner side of the contactless information medium.

A method for producing a contactless information medium according to the present invention includes: an arranging step of arranging a unit, which includes an IC chip and an antenna connected to the IC chip, into a mold for injection molding, with a first surface of the unit facing a bottom face of the mold; and a molding step of performing molding by injecting a resin material into the mold to cover a second surface of the unit, the second surface opposing the first surface.

The above-described method for producing a contactless information medium further includes a second arranging step of releasing a molded piece, which has been manufactured in the molding step, from the mold and arranging the molded piece into a second mold for injection molding different from the mold, with the second surface facing a bottom face of the second mold; and a secondary molding step of performing secondary molding by injecting a resin material into the second mold to cover the first surface of the unit.

In the above-described method for producing a contactless information medium, the antenna is formed of a string of conductive wire, both ends of the conductive wire being connected to the IC chip, and includes a main arrangement pattern provided along a closed curve and a plurality of sub-arrangement patterns, each of which has a smaller diameter than the main arrangement pattern.

In the above-described method for producing a contactless information medium, the unit includes a plurality of bobbins arranged along the closed curve, the string of conductive wire being wound around the bobbins along the closed curve, the string of conductive wire being wound also around each of the bobbins.

### Advantageous Effects of Invention

According to the present invention, a pattern of a coil antenna, which includes a main arrangement pattern forming a closed curve and a plurality of sub-arrangement patterns arranged along the closed curve, is manufactured by winding a conductive wire around a plurality of bobbins arranged along the closed curve. Thus, it becomes possible to easily produce a contactless information medium. Even when the plurality of contactless information media is piled up, each of the contactless information media can communicate with a communication device.

### BRIEF DESCRIPTION OF DRAWINGS

FIG. 1 is a schematic view illustrating an outer appearance of a contactless information medium according to a first embodiment of the present invention.

FIG. 2 is an A-A sectional view of FIG. 1.

FIG. 3 is a top view illustrating a lower body member illustrated in FIG.

FIG. 4A is a top view illustrating a bobbin member.

FIG. 4B is a B-B sectional view of FIG. 4A.

FIG. 5A is a top view illustrating the bobbin member around which a conductive wire is wound.

FIG. 5B is a side view illustrating the bobbin member illustrated in FIG. 5A.

FIG. 6A is a view for describing a method for producing the contactless information medium according to the first embodiment.

FIG. 6B is a view for describing the method for producing the contactless information medium according to the first embodiment.

FIG. 6C is a view for describing the method for producing the contactless information medium according to the first embodiment.

FIG. 7A is a top view illustrating a body member of a contactless information medium according to a second embodiment of the present invention.

FIG. 7B is a D-D sectional view of FIG. 7A.

FIG. 8 is a top view illustrating the body member around which a conductive wire is wound.

FIG. 9 is a sectional view illustrating the contactless information medium according to the second embodiment.

FIG. 10 is a sectional view illustrating a contactless information medium according to a third embodiment of the present invention.

FIG. 11 is a top view illustrating a body member illustrated in FIG. 10.

FIG. 12 is a sectional view illustrating a contactless information medium according to a fourth embodiment of the present invention.

FIG. 13A is a sectional view for describing a method for producing the contactless information medium illustrated in FIG. 12 and illustrating a primary molding step.

FIG. 13B is a perspective view for describing the method for producing the contactless information medium illustrated in FIG. 12 and illustrating a primary molded piece.

FIG. 13C is a perspective view for describing the method for producing the contactless information medium illustrated in FIG. 12 and illustrating the primary molded piece.

FIG. 13D is a sectional view for describing the method for producing the contactless information medium illustrated in FIG. 12 and illustrating a secondary molding step.

FIG. 13E is a perspective view for describing the method for producing the contactless information medium illustrated in FIG. 12 and illustrating a secondary molded piece (final product).

FIG. 14 is a sectional view illustrating a contactless information medium according to a fifth embodiment of the present invention.

FIG. 15 is a view for describing a method for producing the contactless information medium illustrated in FIG. 14.

FIG. 16 is a sectional view illustrating a contactless information medium according to a sixth embodiment of the present invention.

FIG. 17A is a view for describing a method for producing the contactless information medium illustrated in FIG. 16.

FIG. 17B is a view for describing the method for producing the contactless information medium illustrated in FIG. 16.

### DESCRIPTION OF EMBODIMENTS

In the following, embodiments of the present invention will be described in detail with reference to the drawings. Note that the present invention is not limited to the following embodiments. Also, each figure referred to in the following descriptions illustrates a shape, a size, and a positional relationship schematically to make it easy to understand contents of the present invention. That is, the present invention is not limited to a shape, a size, and a positional relationship illustrated as an example in each figure.

### First Embodiment

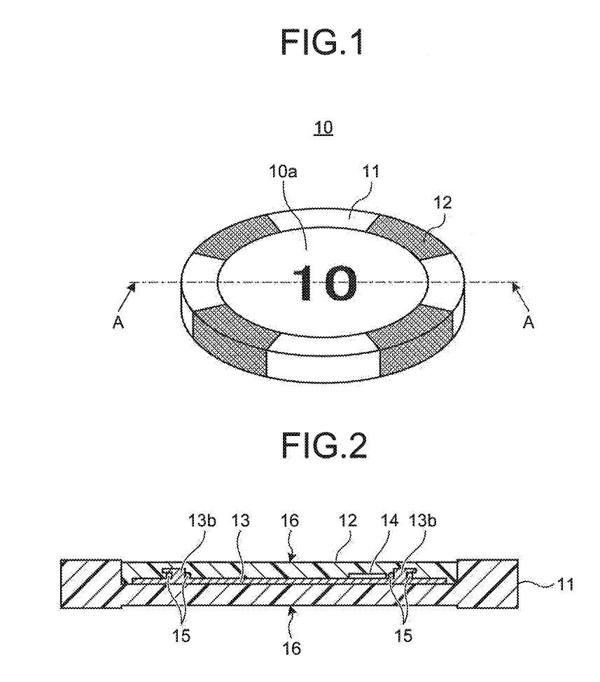

FIG. 1 is a schematic view illustrating an outer appearance of a contactless information medium according to the first embodiment of the present invention. Also, FIG. 2 is an A-A sectional view of FIG. 1.

As illustrated in FIG. 1, a contactless information medium 10 according to the first embodiment has a circular coin shape, and includes a lower body member 11 and an upper body member 12. The lower body member 11 forms a part of a body of the contactless information medium 10. The upper body member 12 forms a part of the body of the contactless information medium 10 and seals, with the lower body member 11, a built-in component of the con tactless information medium 10. Also, labels 10a, on which value and the like of a coin are indicated, are attached to a surface and a rear surface (not illustrated) of the contactless information medium 10. Note that in FIG. 1, a part having a different color is hatched.

As illustrated in FIG. 2, a bobbin member 13, an IC chip 14, and a string of conductive wire 15 are provided inside the contactless information medium 10. The bobbin member 13 is arranged on the lower body member 11. The IC chip 14 is arranged on the bobbin member 13. The conductive wire 15 is wound around bobbins (bobbin part 13b, and auxiliary bobbin parts 13c and 13d, which will be described later) arranged on the bobbin member 13. Shallow recess parts 16 are provided to both surfaces of the contactless information medium 10. The labels 10a are attached to bottom faces of the recess parts 16. Note that the labels 10a are not illustrated in FIG. 2.

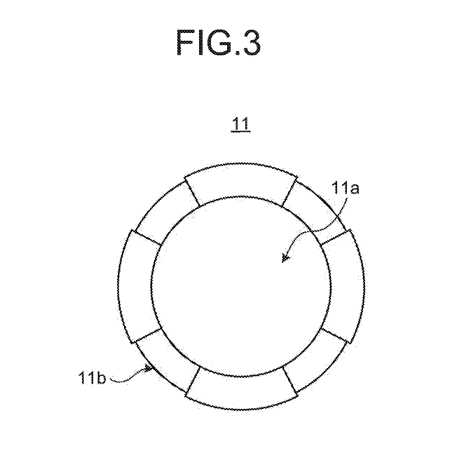

FIG. 3 is a top view illustrating the lower body member 11.

The lower body member 11 is a plate-shaped member which generally has a disk shape. A recess part 11a, on which the bobbin member 13 is arranged, is provided to one principal surface of the lower body member 11. Also, the shallow recess part 16 described above is provided to the other principal surface of the lower body member 11.

A cutout part 11b, which is cut out by a predetermined depth from the outermost periphery, is provided to a peripheral part of the lower body member 11. As described later, the cutout part 11b is a region into which a material of the upper body member 12 is poured during injection molding. Note that by providing such a cutout part 11b and using materials with different colors between the lower body member 11 and the upper body member 12, a design can be put on the surface of the contactless information medium 10.

Such a lower body member 11 is formed, by an injection molding method, from a material in which powder of glass or non-magnetic (or feebly magnetic) metal or alloy is blended into a rigid resin material, such as nylon and acrylonitrile butadiene styrene (ABS) copolymer.

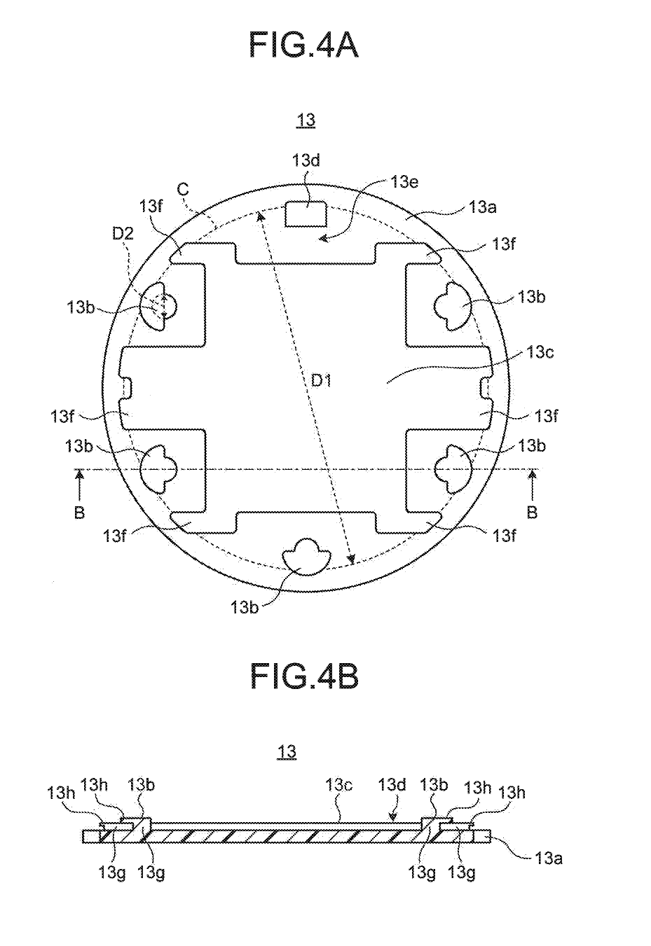

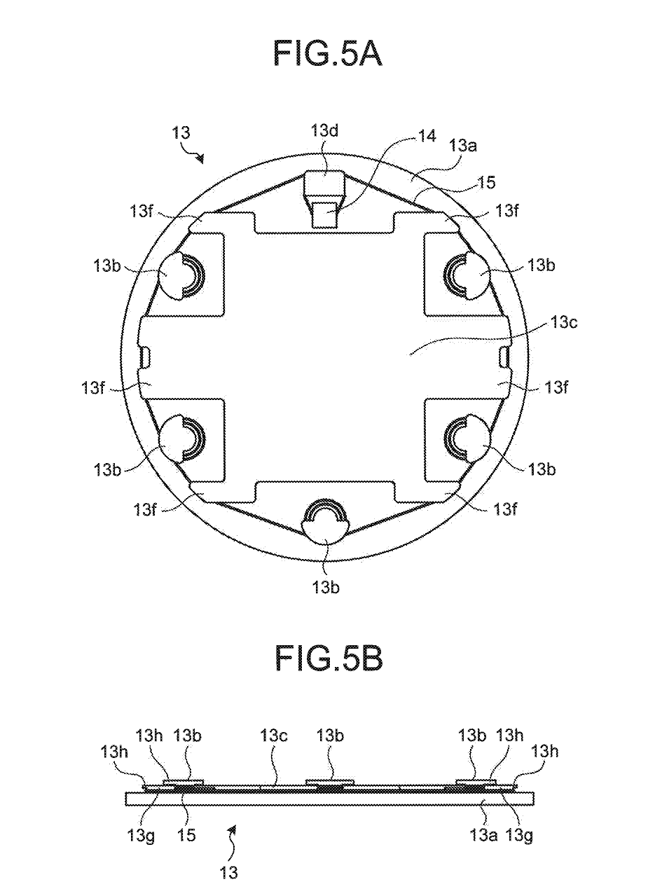

FIG. 4A is a top view illustrating the bobbin member 13. FIG. 4B is a B-B sectional view of FIG. 4A. FIG. 5A is a top view illustrating the bobbin member 13 on which the IC chip 14 and the conductive wire 15 are arranged. FIG. 53 is a side view illustrating the bobbin member 13 and the conductive wire 15 illustrated in FIG. 5A.

The bobbin member 13 is a member around which the conductive wire 15 is wound to form a coil antenna of a predetermined pattern and which keeps the coil antenna of a predetermined pattern. In the first embodiment, as a pattern of the coil antenna, a pattern, which includes a main arrangement pattern forming a closed curve and a plurality of sub-arrangement patterns arranged along the closed curve, is formed. The diameter of each winding shape of the sub-arrangement patterns is smaller than the diameter of the closed curve. In the first embodiment, the closed curve of the main arrangement pattern is a circular shape.

In the bobbin member 13, the bobbin parts 13b and the auxiliary bobbin parts 13c and 13d are connected to each other via a fixation member 13a. Also, a region 13e, in which the IC chip 14 is arranged, is provided on a surface of the fixation member 13a.

The bobbin parts 13b are arranged along the closed curve C. In other words, the bobbin parts 13b are arranged in such a manner that a path, which connects an end region on the side of an outer periphery of each bobbin part 13b to each other, forms the predetermined closed curve C when viewed from the center of the bobbin member 13. Each of the bobbin parts 13b configures a small bobbin around which the conductive wire 15 is wound to form the sub-arrangement pattern.

The auxiliary bobbin part 13c includes a plurality of end parts 13f projected onto the closed curve C. Between the bobbin parts 13b, the end parts 13f make the conductive wire 15, which forms the main arrangement pattern, jut out to the side of the outer periphery along the closed curve C. Note that in the first embodiment, the end parts 13f of the auxiliary bobbin part 13c are extended onto the closed curve C. However, the end parts 13f may be respectively arranged on a plurality of places on the closed curve C, with each of the end parts 13f as an independent auxiliary bobbin part.

The another auxiliary bobbin part 13d is arranged along the closed curve C and makes the conductive wire 15, which forms the main arrangement pattern, jut out to the side of the outer periphery along the closed curve C. Both ends of the conductive wire 15 are connected, via the auxiliary bobbin part 13d, to the IC chip 14 arranged in the region 13e.

The bobbin parts 13b and the auxiliary bobbin parts 13c and 13d, as a whole, configure a large bobbin around which the conductive wire 15 is wound to form the main arrangement pattern. As illustrated in FIG. 4A, the diameter D2 of each of the bobbin parts 13b is smaller than the diameter D1 of the closed curve C. Therefore, the diameter of each of the sub-arrangement patterns becomes smaller than the diameter of the main arrangement pattern. Like this, by making the diameter of the sub-arrangement patterns smaller than that of the main arrangement pattern, each of the contactless information media 10 can send/receive information to/from the communication device (so-called multi-read), even when the plurality of contactless information media. 10 is piled up.

Flange parts 13h are provided at apex parts of each of the bobbin parts 13b and the auxiliary bobbin parts 13c and 13d. The flange parts 13h project to the side of the outer periphery more than core parts 13g around which the conductive wire 15 is wound. The flange parts 13h prevent the conductive wire 15 from falling out of the core parts 13g.

For example, such a bobbin member 13 is formed, by the injection molding method, from a heat-resistant resin material such as polymethylpentene (PMP), polybutylene terephthalate (PBT), liquid crystal polymer (LCP), and polyphenylene sulfide (PPS). Note that the bobbin member 13 only needs to have heat resistance which at least allows the bobbin member 13 to keep its solid condition during the injection molding of the upper body member 12.

Note that the shape of the fixation member 13a is not limited to a disk shape or a tabular shape which are illustrated in FIGS. 4A and 4B. The fixation member 13a. may have any shape as long as the fixation member 13a can fix a relative positional relationship among the bobbin parts 13b and the auxiliary bobbin parts 13c and 13d, and can be placed in the body (between lower body member 11 and upper body member 12). In addition, the bobbin parts 13b and the auxiliary bobbin parts 13c and 13d may be formed integrally with the fixation member 13a by the injection molding or the like, or may be connected to the fixation member 13a by fastening or adhesion. Furthermore, to position the bobbin member 13 during the winding of the conductive wire 15, an opening may be provided to the fixation member 13a, or a cutout or a D-cut may be provided to a part of the outer periphery of the fixation member 13a.

The IC chip 14 is a general electronic module, and a function thereof is not particularly limited. The IC chip 14 may include, for example, a storage part which can store various kinds of data such as individual, information (ID), value, an owner, and a circulation history of the contactless information medium 10.

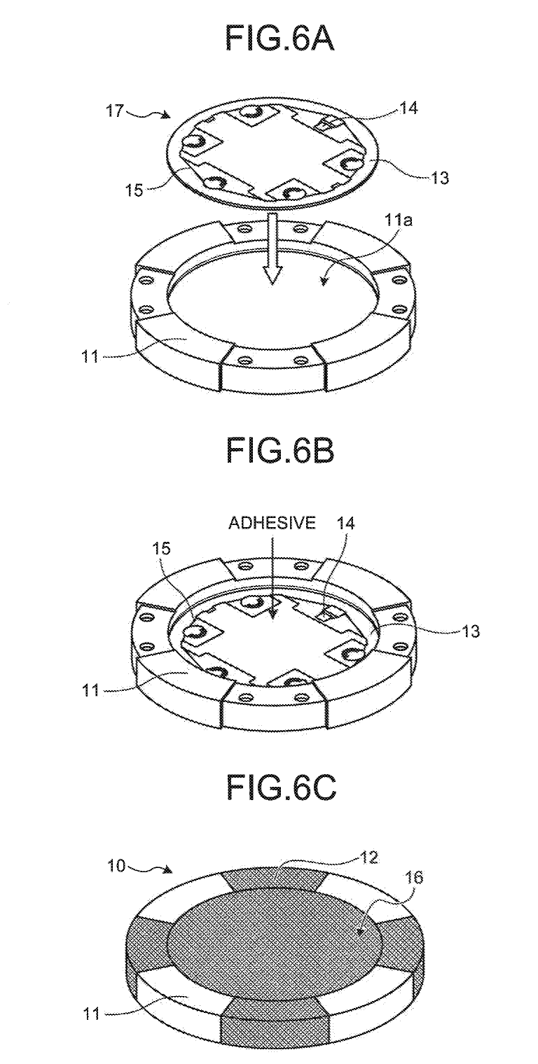

Next, a method for producing the contactless information medium 10 will be described. FIGS. 6A to 6C are views for describing the method for producing the contactless information medium 10. Note that the lower body member 11 and the bobbin member 13 are manufactured in advance from a predetermined resin material by the injection molding method.

First, a pattern of the coil antenna including the main arrangement pattern and the sub-arrangement patterns is formed by winding the conductive wire 15 around the bobbin parts 13b and the auxiliary bobbin part 13c of the bobbin member 13. Note that this step can be done by using a general coil winding machine.

Then, both ends of the conductive wire 15 are connected to the IC chip 14, and the IC chip 14 is temporarily fixed to the predetermined region 13e of the bobbin member 13 with adhesive. Thus, a built-in component 17, in which the bobbin member 13, the IC chip 14, and the conductive wire 15 are integrated, is manufactured (see FIG. 6A).

Next, as illustrated in FIG. 6A, the built-in component 17 is temporarily fixed to the recess part 11a of the lower body member 11 with adhesive. Here, as Illustrated in FIG. 6B, for example, thermosetting or ultraviolet-curing adhesive may be used to cover at least the pattern of the coil antenna to protect the pattern. In this case, the pattern is not destroyed even when heat or pressure is applied during injection molding which is performed in the next step.

Then, the upper body member 12, which covers the recess part 11a and the cutout part 11b of the lower body member 11, is formed by the injection molding method, and the built-in component 17 is sealed. Thus, the contact less information medium 10 illustrated in FIG. 6C is manufactured. Note that in FIG. 60, a part having a different color in the resin material is hatched. Then, the labels 10a are attached to the recess parts 16 on the surfaces of the contactless information medium 10, whereby the contactless information medium 10 is completed.

As described above, according to the first embodiment, a contactless information medium which includes a coil antenna including a main arrangement pattern and a sub-arrangement pattern can be produced. The main arrangement pattern forms a closed curve. The sub-arrangement pattern is arranged along the closed curve and has a winding shape having a smaller diameter than the closed curve.

In such a contactless information medium, electromagnetic mutual interference is small. Therefore, even when the plurality of contactless information media is piled up, communication between each of the contactless information media and a communication device becomes possible. For example, even when the plurality of (for example, ten or more) contactless information media is piled up or heaped up, the communication device can communicate with each of the contactless information media. Thus, even in such a state, various kinds of data, such as individual information (ID) of each of the contactless information media, can be monitored and recorded. In addition, it becomes possible to perform a value check and an authenticity determination of each of the contactless information media extemporarily, to detect the position and the number of the contactless information media, and to calculate the total value thereof.

In addition, according to the first embodiment, the pattern of the coil antenna is formed by winding the conductive wire around the bobbins. Thus, a special winding device is not necessary, and a general manufacturing method using a general coil winding machine can be applied. Therefore, production steps of the contactless information medium become easy, and mass production thereof becomes possible. Thus, the manufacturing cost of a single contactless information medium and initial costs for plant and equipment investment can be reduced.

Also, according to the first embodiment, the coil antenna and the IC chip are arranged in the body member, and sealed with a cover member by the injection molding, with the conductive wire being wound around the bobbins. Thus, the pattern of the coil antenna can be kept without being destroyed even in the injection molding. Therefore, the production steps can be simplified and the costs can be reduced. For example, cumbersome steps during the attachment of the pattern of the coil antenna can be omitted, and the attachment of the film to keep the pattern becomes unnecessary. In addition, it becomes possible to secure performance of each of the contactless information media to communicate even when the plurality of contactless information media is piled up.

Also, according to the first embodiment, it becomes possible to produce the contactless information medium inexpensively, making it possible to use the contactless information medium in a wide range of fields. For example, it becomes possible to use the contactless information medium as a coin (chip) used for various games, such as a card game and a board game, and as a token used in a transportation facility. In addition, the contactless information medium can be used in a game for a kid, and the like.

In the first embodiment described above, the outer shape of the contactless information medium has been described as a circular coin shape. However, various shapes may be selected as the outer shape. Examples of the shape include an oval shape, a polygonal shape such as a square shape, a pentagonal shape, and a hexagonal shape, and a star-like shape in which a plurality of places on the circumference projects to the side of the outer periphery.

Also, in the first embodiment, the main arrangement pattern of the coil antenna has been described as a circular closed curve. However, as long as the sub-arrangement patterns can be arranged along the closed curve, the main arrangement pattern is not limited to the circular shape. For example, the main arrangement pattern may be a closed curve with an oval shape, a polygonal shape such as a square shape, a pentagonal shape, or a hexagonal shape, or a star-like shape. In this case, the arrangements and the shapes of the bobbin parts provided to the bobbin member are changed, according to the pattern of the coil antenna.

Also, in the first embodiment, the pattern of the coil antenna (conductive wire 15) has been formed by the bobbin parts 13b and the auxiliary bobbin part 13c. However, as long as the main arrangement pattern forming the closed curve and the sub-arrangement patterns arranged along the closed curve can be formed with cored coils, the arrangement and the shape of the bobbin parts 13b are not limited to what has been described above. For example, other than the bobbin parts 13b forming the sub-arrangement patterns, one or more bobbins to form the main arrangement pattern may be further provided. Alternatively, the auxiliary bobbin parts 13c and 13d may be omitted and the main arrangement pattern and the sub-arrangement patterns may be formed only by the bobbin parts 13b.

Also, in the first embodiment, the sub-arrangement patterns have been formed inside the main arrangement pattern, but the sub-arrangement patterns may be formed outside the main arrangement pattern.

### Second Embodiment

Next, the second embodiment of the present invention will be described.

An outer appearance of a contactless information medium according to the second embodiment is similar to that of the first embodiment, but an inner configuration of the contactless information medium according to the second embodiment is different from that of the first embodiment. Specifically, in the contactless information medium according to the second embodiment, a bobbin part to form a pattern of a coil antenna is directly provided to a body member. Note that a material of each part configuring the contactless information medium according to the second embodiment is similar to that of the first embodiment. In the second embodiment, a pattern, which includes a main arrangement pattern forming a closed curve and a plurality of sub-arrangement patterns arranged along the closed curve, is formed as a pattern of the coil antenna, like the first embodiment. The diameter of each winding shape of the sub arrangement patterns is smaller than the diameter of the closed curve.

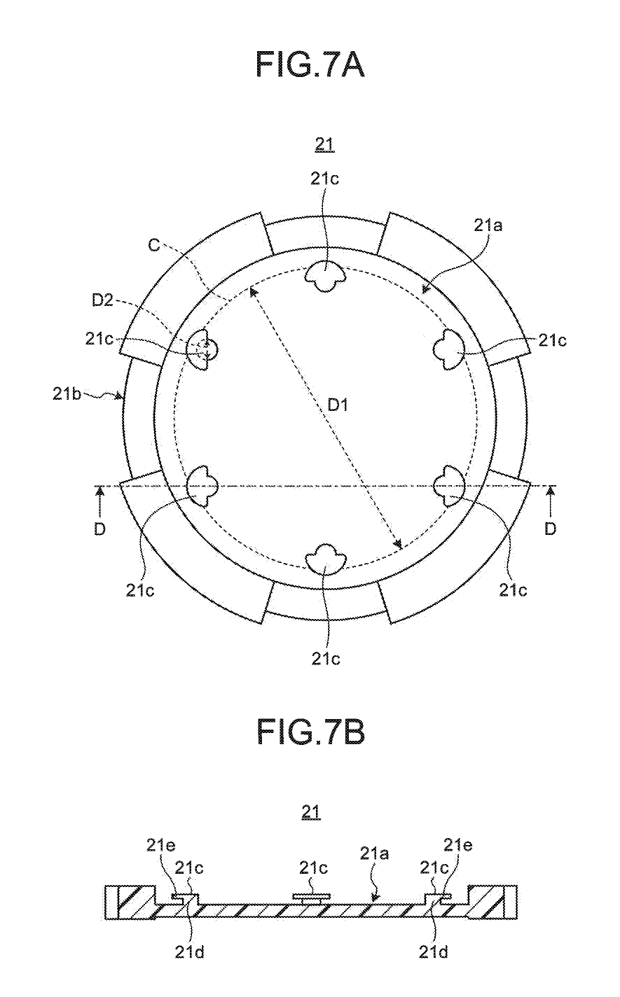

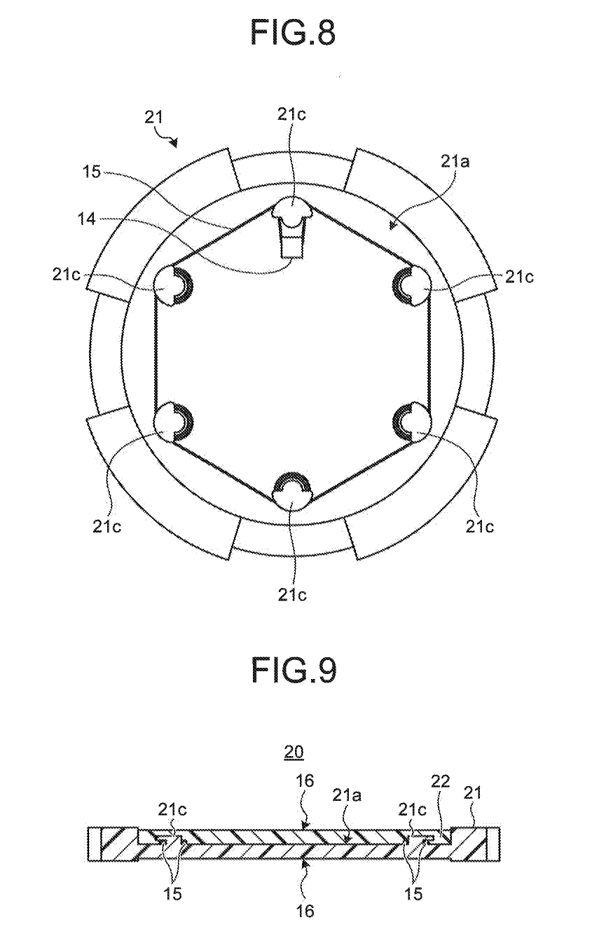

FIG. 7A is a top view illustrating a configuration of the body member of the contactless information medium according to the second embodiment. FIG. 7B is a D-D sectional view of FIG. 7A. FIG. 8 is a top view illustrating the body member illustrated in FIG. 7A on which an IC chip and a conductive wire are arranged.

As illustrated in FIG. 7A, a lower body member 21 according to the second embodiment is a plate-shaped member which generally has a disk shape. A recess part 21a is provided to one principal surface of the lower body member 21. A cutout part 21b, which is cut out by a predetermined depth from the outermost periphery, is provided to a peripheral part of the lower body member 21.

A plurality of bobbin parts 21c protruded from a bottom face of the recess part 21a is provided to the recess part 21a. The bobbin parts 21c are arranged along a closed curve C. In other words, the bobbin parts 21c are arranged in such a manner that a path, which connects an end region on the side of an outer periphery of each bobbin part 21c to each other, forms the predetermined closed curve when viewed from the center of the recess part 21a. The conductive wire 15 is wound around the bobbin parts 21c and forms the main arrangement pattern. Also, the conductive wire 15 is wound around each of the bobbin parts 21c and forms the sub-arrangement patterns. As illustrated in FIG. 7A, the diameter 22 of each of the bobbin parts 21c is adequately smaller than the diameter D1 of the closed curve C. Therefore, the sub-arrangement patterns become smaller than the diameter of the main arrangement pattern.

A flange part 21e is provided at an apex part of each of the bobbin parts 21c. The flange part 21e projects to the side of the outer periphery more than a core part 21d around which the conductive wire 15 is wound. The flange part. 21e prevents the conductive wire 15 from falling out of the core part 21d.

Note that in the second embodiment, like the first embodiment, an auxiliary bobbin part may be provided on the closed curve C and jutted out to the side of the outer periphery of the conductive wire 15 forming the main arrangement pattern. Instead, a bobbin to form the main arrangement pattern may be provided separately from the bobbin parts 21c.

Next, a method for producing the contactless information medium according to the second embodiment will he described. Note that the lower body member 21 is manufactured in advance from a predetermined resin material by the injection molding method.

First, a pattern of the coil antenna including the main arrangement pattern and the sub-arrangement patterns is formed by winding the conductive wire 15 around the bobbin parts 21c of the body member. Note that this step can be done by using a general coil winding machine. Then, both ends of the conductive wire 15 are connected to the IC chip 14, and the IC chip 14 is temporarily fixed to a predetermined region on the bottom face of the recess part 21a with adhesive. Then, for example, thermosetting or ultraviolet-curing adhesive may be solidified at least on the IC chip 14 and the conductive wire 15 for the protection thereof.

Then, as illustrated in FIG. 9, an upper body member 22 to cover the recess part 21a and the cutout part 21b is formed by the injection molding method, and the IC chip 14 and the conductive wire 10 (coil antenna) are sealed. Thus, a contactless information medium 20 is manufactured. Note that like the first embodiment, shallow recess parts 16 may be provided to a surface of the lower body member 21 and a surface of the upper body member 22, and labels may be attached to the shallow recess parts 16.

As described above, according to the second embodiment, the bobbin parts to form the coil antenna are integrated with the body member, whereby the number of components can be reduced. Thus, the production steps can be simplified and the manufacturing costs can be reduced.

### Third Embodiment

Next, the third embodiment of the present invention will be described.

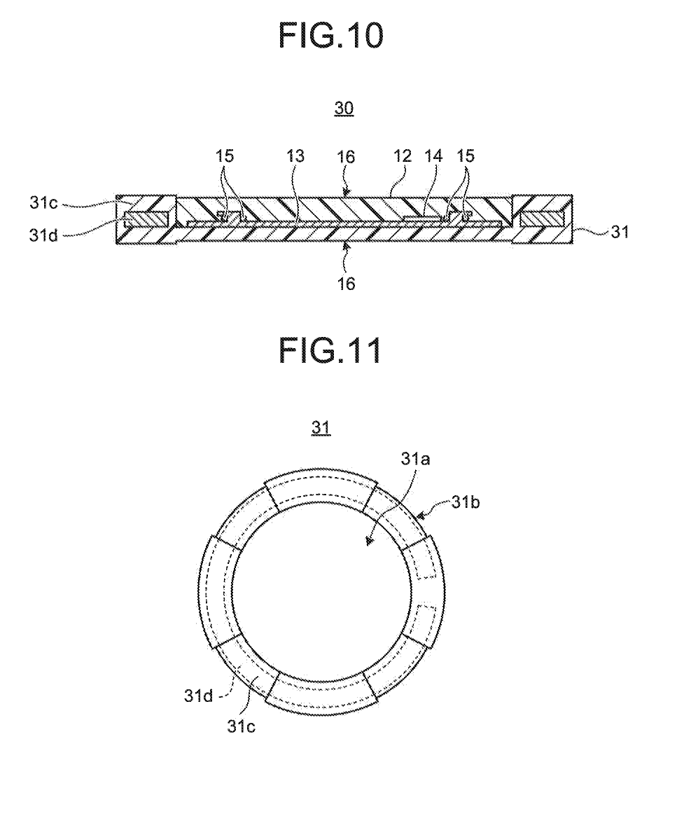

FIG. 10 is a sectional view illustrating a contactless information medium according to the third embodiment of the present invention.

As illustrated in FIG. 10, a contactless information medium 30 according to the third embodiment Includes a lower body member 31, an upper body member 12, a bobbin member 13, an IC chip 14, and a conductive wire 15. Among these, configurations of the upper body member 12, the bobbin member 13, the IC chip 14, and the conductive wire 15 are similar to those of the first embodiment.

FIG. 11 is a top view illustrating the configuration of the lower body member 31. Like the first embodiment, an outer shape of the lower body member 31 generally has a disk shape. On one principal surface of the lower body member 31, a recess part 31a on which the bobbin member 13 is arranged is provided. On a peripheral part of the lower body member 31, a cutout part 31b to be covered by the upper body member 12 is provided.

A metal member 31d is arranged inside a peripheral part 31c which is on the side of the outer periphery more than the recess part 31a of the lower body member 31. A material of the metal member 31d is selected from various kinds of metal or alloy, such as copper, aluminum, or brass, according to the weight required for the contactless information medium 30. The metal member 31d is substantially C-shaped. The C-shape is shaped by cutting a part of a circular ring. Note that the number of metal members 31d arranged in the peripheral part 31c is not limited to one. For example, a plurality of metal members may be arranged in the peripheral part 31c with an interval therebetween.

Such a lower body member 31 is manufactured by performing injection molding with the metal member 31d as a core.

As described above, according to the third embodiment, the metal member is arranged in the peripheral part of the contactless information medium. Thus, the contactless in medium can be weighted with a simple configuration, without interfering with the communication by the coil antenna.

Note that other than this, as a method to weight the contactless information medium, a method to adjust specific gravity of the resin material, which forms the lower body member 31 and the upper body member 12, may be used. The specific gravity is adjusted, for example, by blending metallic powder to the resin material.

Also, in the third embodiment, the bobbin parts may be directly provided to a bottom face of the recess part 31a instead of using the bobbin member 13, like the second embodiment.

### Fourth Embodiment

Next, the fourth embodiment of the present invention will be described.

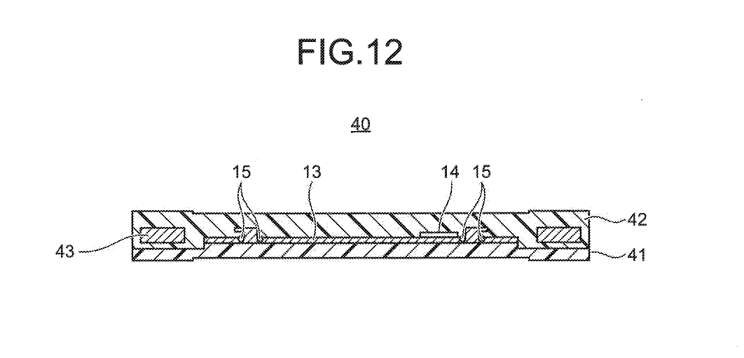

FIG. 12 is a sectional view illustrating a contactless information medium according to the fourth embodiment of the present invention. Note that an outer shape, a material of each part, and a function, of the contactless information medium according to the fourth embodiment are similar to those of the first and third embodiments.

As illustrated in FIG. 12, the contactless information medium 40 according to the fourth embodiment includes a lower body member 41, an caper body member 42, a bobbin member 13, an IC chip 14, a conductive wire 15, and a metal member 43. The lower body member 41 and the upper body member 42 are manufactured by a two-color molding method. The bobbin member 13, the IC chip 14, and the conductive wire 15 are sealed by the lower body member 41 and the upper body member 42. The metal member 43 is sealed inside the upper body member 42. Among these, configurations of the bobbin member 13, the IC chip 14, and the conductive wire 15 are similar to those of the first embodiment. Note that the metal member 43 is not necessary when there is no need to weight the contactless information medium 40.

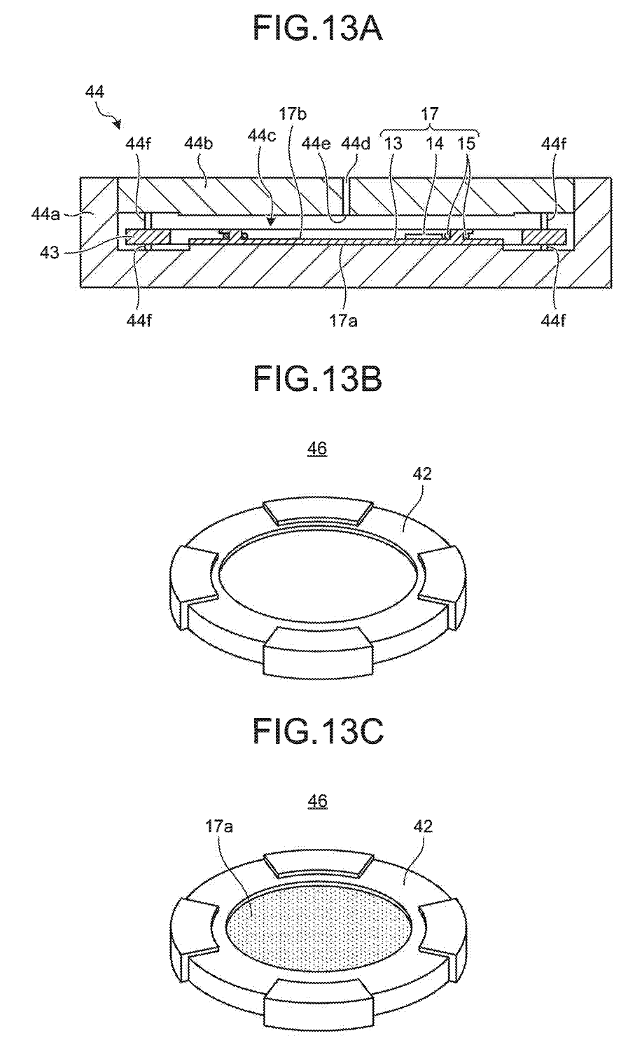

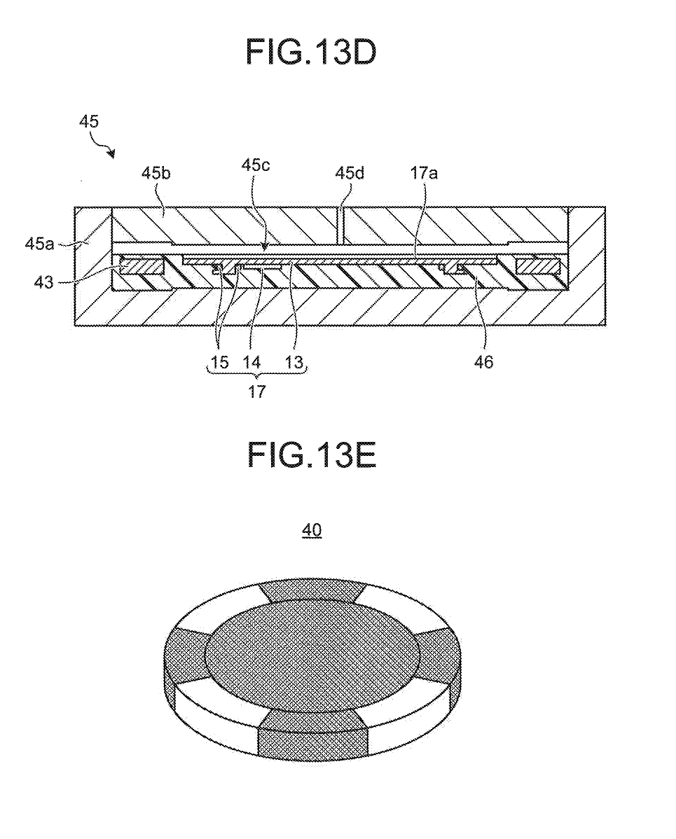

Next, a method for producing the contactless information medium 40 will be described. FIGS. 13A to 13E are views for describing the method for producing the contactless information medium 40. Here, a built-in component 17 in which the bobbin member 13, the IC chip 14, and the conductive wire 15 are integrated (see FIGS. 5A and 5B) is manufactured in advance. In the manufacture, the IC chip 14 and the conductive wire 15 may be covered with adhesive or the like in order to protect the IC chip 14 and to keep a winding pattern of tale conductive wire 15. Also, an opening, a cutout, a D-cut, or the like (none of them are illustrated) may be provided to the bobbin member 13 for the positioning thereof in a mold used in injection molding described in the following.

First, as illustrated in FIG. 13A, the built-in component 17 and the metal member 42 are arranged in a mold 44 for injection molding. The mold 44 includes a lower mold 44a and an upper mold 44b. A cavity 44c surrounded by the lower mold 44a and the upper mold 44b has a shape corresponding to the shape of the upper body member 42 illustrated in FIG. 12. A recess and a protrusion (not illustrated) corresponding to an image given to a surface of the contactless information medium 40 are provided to the cavity 44c. In such a mold 44, the built-in component 17 is positioned and directly placed on an inner bottom face of the lower mold 44a, with a rear surface 17a (surface on the opposite side of the surface on which the IC chip 14 and the conductive wire 15 are arranged) facing the inner bottom face. Meanwhile, the metal member 43 is held by pins 44f provided to the lower mold 44a and the Upper mold 44b.

Note that in FIG. 13A, the inner bottom face of the lower mold 44a is an even flat surface. However, a step may be provided between a region in which the built-in component 17 is placed and a region in which the metal member 43 is placed, and positions in the thickness direction of the built-in component 17 and the metal member 43 in the contactless information medium 40 may be adjusted. Also, when an opening or the like for the positioning is provided to the bobbin member 13, a protrusion or the like corresponding to the opening is preferably provided to the inner bottom face of the lower mold 44a.

Then, primary molding is performed by injecting a melted resin material into the cavity 44c through a sprue 44d. Thus, the upper body member 42 is formed, and a surface 17b of the built-in component. 17 is covered. Here, by optimizing a position of a gate 44e and the direction of injecting the resin material, the built-in component 17 is pressed by injection pressure of the resin material. Note that a resin material having a base color is used in the primary molding step.

Then, a primary molded piece manufactured in the primary molding step is released from the mold 44. FIGS. 13B and 13C are perspective views illustrating the primary molded piece. As illustrated in FIG. 13B, an entire surface on one side (on the side of the surface 17b of the built-in component 17) of a primary molded piece 46 is covered with the resin material. On the one hand, as illustrated in FIG. 13C, the rear surface 17a of the built-in component 17 is exposed on the other surface of the primary molded piece 46.

Then, as illustrated in FIG. 13D, the primary molded piece 46 is arranged in a mold 45 for injection molding, with the rear surface 17a of the built-in component 17 facing upward. The mold 45 includes a lower mold 45a and an upper mold 45b. A cavity 45c surrounded by the lower mold 45a and the upper mold 45b has a shape corresponding to the shape of the lower body member 41 illustrated in FIG. 12.

Then, secondary molding is performed by injecting a melted resin material into the cavity 45c through a sprue 45d. Note that a resin material used in the secondary molding step has a different color from the resin material used in the primary molding step. In the secondary molding step, the lower body member 41 is formed and the built-in component 17 is sealed. Also, the recess (not illustrated) provided to the surface of the primary molded piece is filled with the resin material having a different color and the image is formed. Then, by releasing a secondary molded niece from the mold 45, the contactless information medium 40 in the shape of a final product can be obtained, as illustrated in FIG. 13E. Note that in FIG. 13E, a part having a different color in the resin material is hatched.

As described above, in the fourth embodiment, the built-in component 17 is directly placed in the mold 44 for injection molding, and one surface of the built-in component 17 is covered while the upper body member 42 is formed. Thus, it is possible to reduce laboring hours and production steps considerably, to shorten lead time, and to further reduce costs, compared to the production method of the first embodiment in which the lower body member 11 (see FIG. 6A) is separately manufactured and injection molding is performed after the built-in component 17 is fixed to the lower body member 11 with adhesive, an adhesive tape, or the like. Also, the production method of the contactless information medium 40 according to the fourth embodiment is suitable for an automated production line, and thus makes it possible to produce a large quantity of contactless information media 40 effectively.

Note that in the fourth embodiment, surface colors of center parts are different between the lower body member 41 and the upper body member 42, but by attaching labels to the center parts, the coin-shaped contactless information medium can be used without any problem.

Also, in the fourth embodiment, the built-in component 17, in which the bobbin member 13, the IC chip 14, and the conductive wire 15 are integrated, is sealed by the two-color molding method. However, instead of the built-in component 17, a sheet-like coil unit, an RFID inlay, a substrate module, or the like may be arranged and the contactless information medium may be manufactured in a similar production method. In the sheet-like coil unit, an air core coil is sandwiched between adhesive films or the like. In the RFID inlay, an IC chip and an antenna are arranged on a PET film or the like. Note that it is preferable, for example, to cover the surface with adhesive or the like in advance for protection, in order not to damage these built-in components by heat and pressure of molded resin.

### Fifth Embodiment

Next, the fifth embodiment of the present invention will be described.

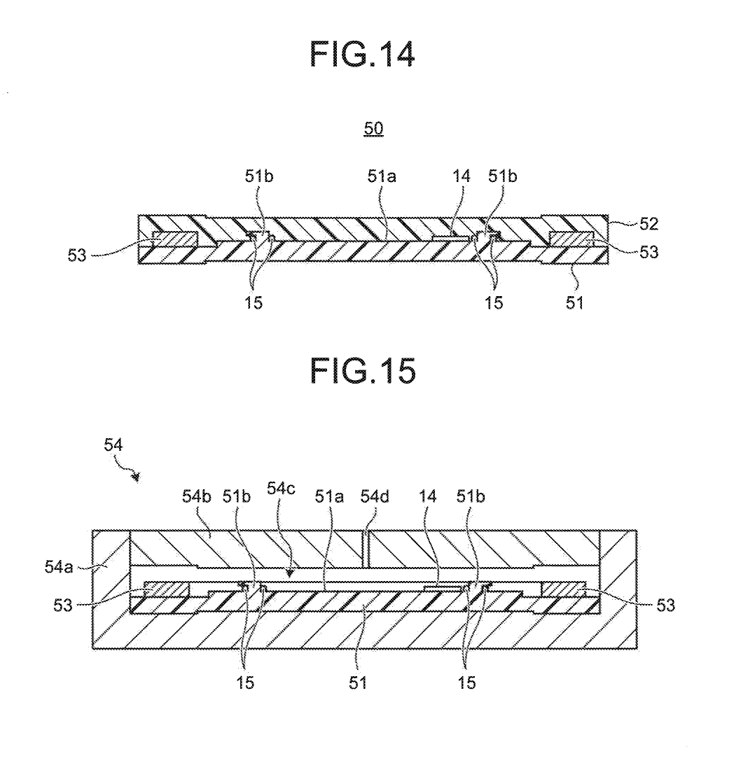

FIG. 14 is a sectional view illustrating a contactless information medium according to the fifth embodiment of the present invention. Note that an outer shape, a material of each part, and a function, of the contactless information medium according to the fifth embodiment are similar to those of the first and third embodiments.

As illustrated in FIG. 14, a contactless information medium 50 according to the fourth embodiment includes a lower body member 51, an upper body member an IC chip 14, a conductive wire 15, and a metal member 53. The IC chip 14, the conductive wire 15, and the metal member 53 are sealed by the lower body member 51 and the upper body member 52. Note that the metal member 53 is not necessary when there is no need to weight the contactless information medium 50.

To an inner surface 51a of the lower body member 51, a plurality of bobbin parts 51b protruded from the inner surface 51a is provided. The conductive wire 15 is wound around the bobbin parts 51b. Note that the shape and the arrangement of the bobbin parts 51b are similar to those of the bobbin parts 21c illustrated in FIG. 7A. The winding pattern of the conductive wire 15 is similar to that in FIG. 8.

Note that in the fifth embodiment, a peripheral part of the lower body member 51 is one step lower than a center part thereof, in order to adjust the position in the thickness direction of the metal member 53 in the contactless information medium 50. However, the center part and the peripheral part may be on the same flat surface.

Next, a method for producing the contactless information medium 50 will be described. FIG. 15 is a view for describing the method for producing the contactless information medium 50.

First, the lower body member 51 is manufactured by the injection molding method. Then, the conductive wire 15 is wound around the bobbin parts 51b, and the IC chip connected to the conductive wire 15 is fixed to the inner surface 51a with adhesive or the like. Here, the peripheral part of the lower body member 51 is lower than the bobbin parts 51b. Therefore, the conductive wire 15 can be easily wound around the bobbin parts 51b using a general coil winding machine. Note that the IC chip 14 and the conductive wire 15 may be covered with adhesive or the like in order to protect the IC chip 14 and to keep a winding pattern of the conductive wire 15.

Then, as illustrated in FIG. 15, the lower body member 51, in which the IC chip 14 and the conductive wire 15 are arranged, is placed in a mold 54 for injection molding, and the metal member 53 is placed in the peripheral part of the lower body member 51. The mold 54 includes a lower mold 54a and an upper mold 54b. Note that in the placement, the metal member 53 may be fixed to the lower body member 51 with adhesive. A cavity 54c surrounded by the lower mold 54a and the upper mold 54b has a shape corresponding to the shape of the upper body member 52 illustrated in FIG. 14.

Then, injection molding is performed by injecting a melted resin material into the cavity 54c through a sprue 54d. Then, by releasing a molded piece from the mold 54, the contactless information medium 50 in the shape of a final product can be obtained.

### Sixth Embodiment

Next, the sixth embodiment of the present invention will be described.

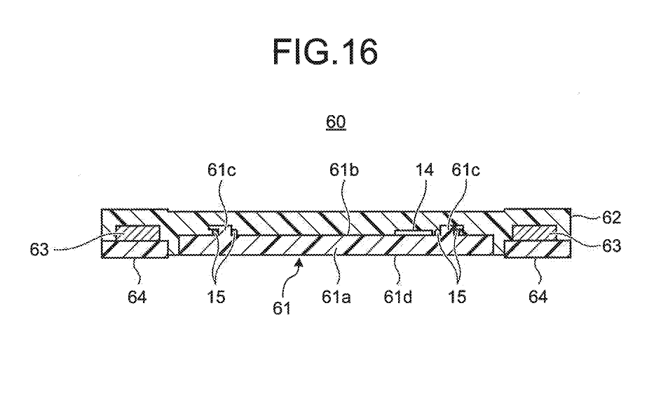

FIG. 16 is a sectional view illustrating a contactless information medium according to the sixth embodiment of the present invention. Note that an outer shape, a material of each part, and a function, of the contactless information medium according to the sixth embodiment are similar to those of the first and third embodiments.

As illustrated in FIG. 16, a contactless information medium 60 according to the sixth embodiment includes a bobbin member 61, a body member 62, an IC chip 14, a conductive wire 15, a metal member 63, and a surface member 64. The IC chip 14 and the conductive wire 15 are sealed by the bobbin member 61 and the body member 62. The surface member 64 seals the metal member 63 with the body member 62. Note that the metal member 63 is not necessary when there is no need to weight the contactless information medium 60.

The bobbin member 61 includes a bobbin base 61a and a plurality of bobbin parts 61c provided to an inner surface 61b of the bobbin base 61a. The conductive wire 15 is wound around the bobbin parts 61c. Note that the shape and the arrangement of the bobbin parts 61c are similar to those of the bobbin parts 13b illustrated in FIG. 4A. The winding pattern of the conductive wire 15 is similar to that in FIG. 5A.

The bobbin base 61a is thicker than the fixation member 13a illustrated in FIG. 4B. Also, an outer surface 61d of the bobbin base 61a is exposed to a surface of the contactless information medium 60. That is, the bobbin base 61a configures a part of a body of the contactless information medium 60. Note that as described above, the bobbin base 61a may be formed from a material similar to the material of the bobbin member 13 of the first embodiment, or a material similar to the material of the lower body member 11 and the upper body member 12 of the first embodiment. In a case of using the material similar to that of the bobbin member 13, in order to weight the contactless information medium 60, a material having greater specific gravity than the following materials may be added to the following materials. The materials are, for example, heat-resistant resin materials such as polymethylpentene (PMP), polybutylene terephthalate (PBT), liquid crystal polymer (LCP), and polyphenylene sulfide (PPS).

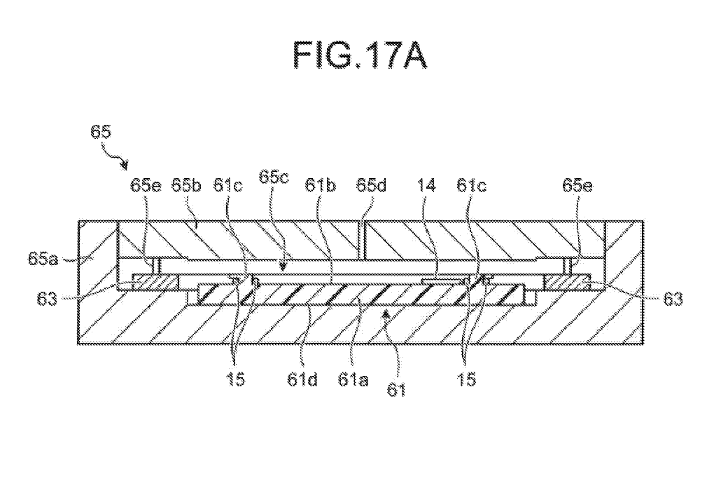

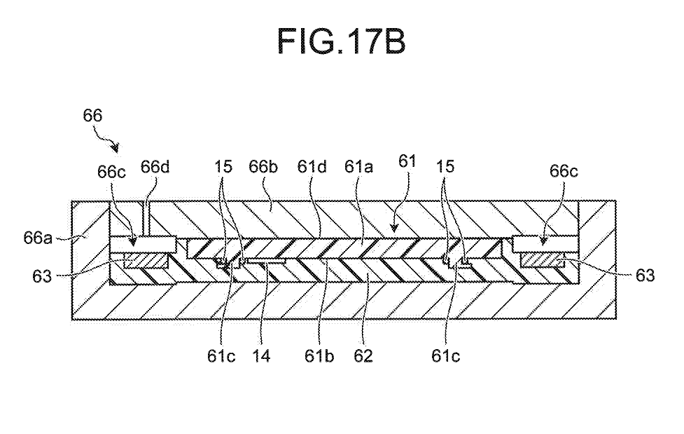

Next, a method for producing the contactless information medium 60 will be described. FIGS. 17A and 17B are views for describing the method for producing the contactless information medium 60.

First, the bobbin member 61 is manufactured by the injection molding method. Then, the conductive wire 15 is wound around the bobbin parts 61c, and the IC chip 14 connected to the conductive wire 15 is fixed to the inner surface 61b with adhesive or the like. Here, the inner surface 61b of the bobbin member 61 is a flat surface. Therefore, the conductive wire 15 can be easily wound around the bobbin parts 61c by a general, coil winding machine. Note that the IC chip 14 and the conductive wire 15 may be covered with adhesive or the like in order to protect the IC chip 14 and to keep a winding pattern of the conductive wire 15.

Then, as illustrated in FIG. 17A, the bobbin member 61, on which the IC chip 14 and the conductive wire 15 are arranged, is placed in a mold 65 for injection molding, and the metal member 63 is placed on the side of an outer periphery of the bobbin member 61. The mold 65 includes a lower mold 65a and an upper mold 65b. A cavity 65c surrounded by the lower mold. 65a and the upper mold 65b has a shape corresponding to the shape of the body member 62 illustrated in FIG. 16. A recess and a protrusion (not illustrated) corresponding to an image given to a surface of the contactless information medium 60 are provided to the cavity 65c. Also, a step is provided to a peripheral part of an inner bottom face of the lower mold 65a in order to adjust the height, of the metal member 63 in the contactless information medium 60. Furthermore, a pin 65e, which holds the metal member 63, is provided to the upper mold 65b.

Then, primary molding is performed by injecting a melted resin material into the cavity 65c through a sprue 65d. The IC chip 14 and the conductive wire 15 wound around the bobbin parts 61c are sealed in the primary molding step.

Then, a primary molded piece is released from the mold 65 and arranged, as illustrated in FIG. 17B, in a mold 66 for injection molding, the mold 66 including a lower mold 66a and an upper mold 66b. The primary molded piece is arranged with a rear surface 61d facing the upper mold 66b. A cavity 66c surrounded by the lower mold 66a and the upper mold 66b has a shape corresponding to the shape of the peripheral part of the contactless information medium 60 illustrated in FIG. 16.

Then, secondary molding is performed by injecting a melted resin material into the cavity 66c through a sprue 66d. Note that a resin material used in the secondary molding step has a different color form the resin material used in the primary molding step. In the secondary molding step, the metal member 63 is sealed. Also, the recess (not illustrated) provided to the surface of the primary molded piece is filled with the resin material having a different color and the image is formed. Then, by releasing a secondary molded piece from the mold 66, the contactless information medium 60 in the shape of a final product can be obtained.

Note that in the sixth embodiment, surface colors and materials of center parts are different between both surfaces of the contactless information medium 60, but by attaching labels to the center parts, the coin-shaped contactless information medium can be used without any problem.

### REFERENCE SIGNS LIST

10,20,30,40,50,60 contactless information medium

10a label

11,21,31,41,51 lower body member

11a,21a,31a recess part

11b,21b,31b cutout part

12,22,42,52 upper body member

13,61 bobbin member

13a fixation member

13b,21c,51b,61c bobbin part

13c,13d auxiliary bobbin part

13e region

13f end part

13g,21d core part

13h,21e flange part

14 IC chip

15 conductive wire

16 recess part

17 built-in component

17a rear surface

17b surface

31c peripheral part

31d,43,53,63 metal member

44,45,54,65,66 mold

44a,45a,54a,65a,66a lower mold

44b,45b,54b,65b,66b upper mold

44c,45c,54c,65c,66c cavity

44d,45d,54d,65d,66d sprue

44e gate

44f,65e pin

46 primary molded piece

51a,61b inner surface

61a bobbin base

61d outer surface

62 body member

64 surface member

1. A contactless information medium comprising:
a body forming an outer shape of the contactless information medium;
an IC chip housed in the body;
a coil antenna which is formed of a string of conductive wire, both ends of the conductive wire being connected to the IC chip, and which includes a main arrangement pattern provided along a closed curve and a plurality of sub-arrangement patterns, each of which has a smaller diameter than the main arrangement pattern; and
a plurality of bobbins provided in the body and arranged along the closed curve, the string of conductive wire being wound around the plurality of bobbins along the closed curve to form the main arrangement pattern, the string of conductive wire being wound around each of the bobbins to form the sub-arrangement patterns.

2. The contactless information medium according to claim 1, further comprising an auxiliary bobbin which is arranged along the closed curve and makes the string of conductive wire, which forms the main arrangement pattern, jut out to a side of an outer periphery.

3. The contactless information medium according to claim 1, wherein
the body comprises:
a first member which forms a part of the body; and
a second member which forms a part of the body and seals, with the first member, the plurality of bobbins, the IC chip, and the coil antenna, and
the plurality of bobbins is connected to each other by a fixation member, which fixes the plurality of bobbins, and housed between the first member and the second member.

4. The contactless information medium according to claim 3, further comprising a metal member arranged on a side of an outer periphery of the fixation member,
wherein the fixation member is arranged on a surface, located on an inner side of the contactless information medium, of the first member, with the plurality of bobbins facing a side of the second member, and
the metal member is sealed inside the first member.

5. The contactless information medium according to claim 3, further comprising a metal member arranged on a side of an outer periphery of the fixation member and sealed inside the second member.

6. The contactless information medium according to claim 1, wherein
the body comprises:
a first member which forms a part of the body; and
a second member which forms a part of the body and seals, with the first member, the plurality of bobbins, the IC chip, and the coil antenna, and
the plurality of bobbins is provided on a surface, located on an inner side of the contactless information medium, of either the first member or the second member.

7. The contactless information medium according to claim 6, further comprising a metal member arranged on a side of an outer periphery of the plurality of bobbins, wherein
the plurality of bobbins is provided on a surface, located on an inner side of the contactless information medium, of the first member, and
the metal member is sealed inside the first member.

8. The contactless information medium according to claim 6, further comprising a metal member arranged on a side of an outer periphery of the plurality of bobbins, wherein
the plurality of bobbins is provided on a surface, located on an inner side of the contactless information medium, of the first member, and
the metal member is sealed by the first member and the second member.

9. The contactless information medium according to claim 6, further comprising a metal member arranged on a side of an outer periphery of the plurality of bobbins, wherein
the plurality of bobbins is provided on a surface, located on an inner side of the contactless information medium, of the first member, and
the metal member is sealed by the second member and a third member which is different from the first member.

10. The contactless information medium according to claim 1, wherein the body is coin-shaped.

11. A bobbin member for a contactless information medium, around which bobbin member a conductive wire is wound to form a predetermined pattern of a coil antenna in the contactless information medium, the bobbin member comprising:
a plurality of bobbins arranged along a closed curve; and
a fixation member which connects the plurality of bobbins to each other.

12. A body member for a contactless information medium according to claim 1, which body member forms a part of a body of the contactless information medium, the body member comprising:
a plurality of bobbins arranged along a closed curve on a surface on an inner side of the contactless information medium.

13. A method for producing a contactless information medium, comprising:
an arranging step of arranging a unit, which includes an IC chip and an antenna connected to the IC chip, into a mold for injection molding, with a first surface of the unit facing a bottom face of the mold; and
a molding step of performing molding by injecting a resin material into the mold to cover a second surface of the unit, the second surface opposing the first surface.

14. The method for producing a contactless information medium according to claim 13, further comprising:
a second arranging step of releasing a molded piece, which has been manufactured in the molding step, from the mold and arranging the molded piece into a second mold for injection molding different from the mold, with the second surface facing a bottom face of the second mold; and
a secondary molding step of performing secondary molding by injecting a resin material into the second mold to cover the first surface of the unit.

15. The method for producing a contactless information medium according to claim 13, wherein the antenna is formed of a string of conductive wire, both ends of the conductive wire being connected to the IC chip, and includes a main arrangement pattern provided along a closed curve and a plurality of sub-arrangement patterns, each of which has a smaller diameter than the main arrangement pattern.

16. The method for producing a contactless information medium according to claim 15, wherein the unit comprises a plurality of bobbins arranged along the closed curve, the string of conductive wire being wound around the bobbins along the closed curve, the string of conductive wire being wound also around each of the bobbins.
